(19) United States
(12) Patent Application Publication
(10) Pub. No.: US 2025/0041973 A1
(43) Pub. Date: Feb. 6, 2025

(54) Direct 3D Laser Engraved Gasket For Parts Used In Semiconductor Processing

(71) Applicant: Applied Materials, Inc., Santa Clara, CA (US)

(72) Inventors: Chih-Yang CHANG, Santa Clara, CA (US); Shannon WANG, Santa Clara, CA (US); Dien-yeh WU, San Jose, CA (US); Yao-Hung YANG, Santa Clara, CA (US); Tom K. CHO, Los Altos, CA (US)

(21) Appl. No.: 18/230,615

(22) Filed: Aug. 4, 2023

(51) Int. Cl. B23K 26/362; H01L 21/67

(52) U.S. Cl. CPC B23K 26/362; H01L 21/67126; B23K 2101/40; B23K 2103/42

(57) ABSTRACT

Embodiments of methods of creating a gasket for parts used in semiconductor processing are provided herein. In some embodiments, a method of creating a gasket includes: applying an elastomer material on a surface of a part used for substrate processing; and laser engraving the elastomer material to form the elastomer gasket to define a sealing surface on the part.

### FIELD

Embodiments of the present disclosure generally relate to semiconductor processing of semiconductor substrates.

### BACKGROUND

Gaskets are used to seal apparatus from external environments or to prevent gases from escaping during semiconductor substrate processing. In some cases, the gaskets can be inserted into grooves or placed on flat surfaces to provide a seal between two mating surfaces. Smaller gasket sizes are typically easy to manipulate into position. However, the inventors have observed that larger gaskets tend to be stretched out of shape when positioning into place. Changes in the gasket shape can lead to poor sealing between the mating surfaces. The inventors also observed that when a person is involved in the manual installation of the gasket, the amount of deformation can vary depending on the particular person doing the installation. The inconsistencies lead to further gasket and part failures.

Accordingly, the inventors have provided improved methods of creating a gasket.

### SUMMARY

Embodiments of methods of creating a gasket for parts used in semiconductor processing are provided herein. In some embodiments, a method of creating a gasket includes: applying an elastomer material on a surface of a part used for substrate processing; and laser engraving the elastomer material to form the elastomer gasket to define a sealing surface on the part.

In some embodiments, a method of creating a gasket includes: cleaning a part used for substrate processing, the part having a surface that includes a gasket groove for interfacing with an elastomer gasket; adjusting a desired dimension of the elastomer gasket to compensate for changes to the gasket groove caused by cleaning the part; applying an elastomer material on the surface; and laser engraving the elastomer material to form the elastomer gasket with the desired dimension to define a sealing surface.

In some embodiments, a non-transitory, computer readable medium having instructions stored thereon that, when executed, cause a method for creating an elastomer gasket to be performed, the method including: applying an elastomer material on a surface of a part used for substrate processing; and laser engraving the elastomer material via a laser to form the elastomer gasket to define a sealing surface on the part.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method of creating a gasket in accordance with at least some embodiments of the present disclosure.

FIG. 2 depicts a cross-sectional view of a process chamber in accordance with at least some embodiments of the present disclosure.

FIG. 3 depicts a cross-sectional top view of a cooling apparatus with a spiral gasket groove in accordance with at least some embodiments of the present disclosure.

FIG. 4 depicts an isometric view of a laser engraving machine in accordance with at least some embodiments of the present disclosure.

FIG. 5A depicts a schematic side view of a part after applying an elastomer material on a surface of the part having gasket grooves in accordance with at least some embodiments of the present disclosure.

FIG. 5B depicts a schematic side view of a part after partially completing a laser engraving process on an elastomer material that is applied on a surface of the part having gasket grooves in accordance with at least some embodiments of the present disclosure.

FIG. 5C depicts a schematic side view of a part after fully completing a laser engraving process on an elastomer material that is applied on a surface of the part having gasket grooves in accordance with at least some embodiments of the present disclosure.

FIG. 6A depicts schematic side views of a portion of a part having a first type of gasket groove at various points of gasket formation in accordance with at least some embodiments of the present disclosure.

FIG. 6B depicts schematic side views of a portion of a part having a second type of gasket groove at various points of gasket formation in accordance with at least some embodiments of the present disclosure.

FIG. 6C depicts schematic side views of a portion of a part having a third type of gasket groove at various points of gasket formation in accordance with at least some embodiments of the present disclosure.

FIG. 7A depicts a schematic side view of a part after applying an elastomer material on a surface of the part in accordance with at least some embodiments of the present disclosure.

FIG. 7B depicts a schematic side view of a part after partially completing a laser engraving process on an elastomer material that is applied on a surface of the part in accordance with at least some embodiments of the present disclosure.

FIG. 7C depicts a schematic side view of a part after fully completing a laser engraving process on an elastomer material that is applied on a surface of the part in accordance with at least some embodiments of the present disclosure.

FIG. 8 depicts cross-sectional views of gasket profiles in accordance with at least some embodiments of the present disclosure.

FIG. 9 depicts schematic side views of a laser engraving machine having components that may be tilted to form elastomer gaskets disposed in undercut gasket grooves in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods of forming gaskets for parts used for substrate processing are provided herein. The methods provide processes for in-situ formation of gaskets via applying an elastomer material on the part and laser engraving the elastomer material to form a gasket having the desired size and shape. As such, the gasket may be directly bonded to the part, and therefore, requires no installation. The in-situ formation process eliminates gasket stretching variations caused by manual installation of gaskets, dramatically increasing the sealing integrity and performance of the gaskets. In some embodiments, the laser engraving to form gaskets allows a variety of gasket shapes to be formed in a variety of groove shapes based on the sealing requirements of the part.

The methods provided herein also enable the ability to have unlimited recycle cleaning of a part because the gasket size can be customized to adapt to an after-cleaning groove size increase. In some embodiments, the gasket size can be adjusted for each cycle of cleaning (number of cycles) to compensate for the increasing groove sizes due to the cleaning process. Adjusting the gasket size to accurately account for a gasket groove decreases the inconsistencies between gasket groove sizes and advantageously prevents crosstalk and/or leakage of the gasket.

Manual gasket installation introduces unwanted gasket stretches that are evident through the varying lengths of gasket left after each installation. Each individual installer may pull more or less on the gasket during installation leaving the gasket deformed and various amounts of gasket “remnants” after installation. The deformation reduces the quality of the seal provided by the gasket. For example, the inventors have observed crosstalk leak issues between spiral channels between a showerhead of a process chamber and a cooling assembly used to cool the showerhead in the process chamber. The poor sealing of the spiral gasket leads to temperature variations and thermal damage. The inventors have also observed that after the apparatus is cleaned or recycled using an etching process, the size of the gasket grooves increased, leading to further sealing issues and ultimately limiting the number of cleaning cycles that an apparatus can undergo (reducing the working lifetime of the apparatus). The methods of the present principles solve the issues and also allow formation of different shapes of gaskets (e.g., round, rectangular, spiral, etc.) that can be adjusted to a given surface, groove, or length. The gaskets can also be formed in-situ, not only in gasket grooves, but also on flat sealing surfaces such as sealing surfaces of a slit valve door and the like.

As used herein, the term “gasket” includes gaskets formed in a closed loop or gaskets formed in an open loop. A closed loop gasket may have any loop shape such as, for example but not meant to be limiting, a round or o-ring loop shape, a rectangular loop shape, or a loop shape that mimics a part shape and the like. An open loop gasket, for example but not meant to be limiting, may be installed in a part in a straight or linear fashion and/or the open loop gasket may be curved during installation to follow along a part shape or gasket groove and/or may extend around a corner of a part and the like. A “profile” of a gasket is used herein is a cross-sectional shape of the gasket. As noted below and with examples depicted in FIG. 8, a gasket's profile may have a variety of shapes. In some embodiments, the profile shape may change over the length of the gasket. Changes in profile shape over the length of the gasket may be due to changes in the sealing surfaces of the part that may require more or less gasket material to provide adequate sealing properties and/or change in profile to provide more or less sealing properties such as more or less pressure and the like at different points of the sealing surface.

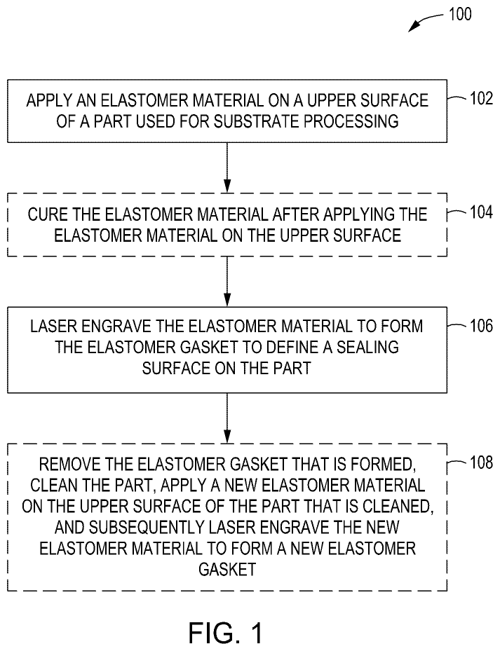

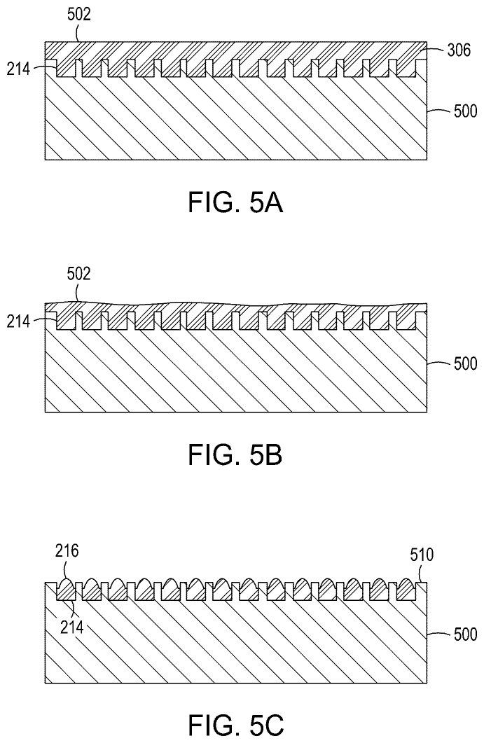

FIG. 1 depicts a flow chart of a method 100 of creating a gasket in accordance with at least some embodiments of the present disclosure. At 102, the method 100 includes applying an elastomer material (e.g., elastomer material 502), as shown in FIG. 5A, on a surface (e.g., surface 306) of a part (e.g., cooling apparatus 212, part 500) used for substrate processing. In some embodiments, applying the elastomer material comprises applying a liquid elastomer material via pouring, spin coating, or the like. In some embodiments, the elastomer gasket comprises a thermoplastic polyurethane material, a thermoplastic elastomer material, or a thermoplastic copolyester material. In some embodiments, the elastomer gasket is formed of one type of material.

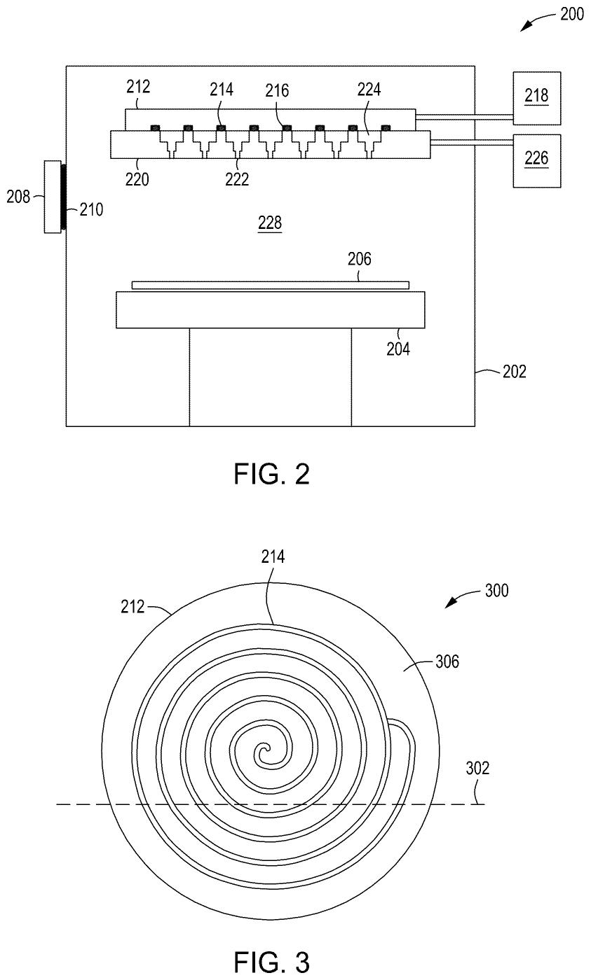

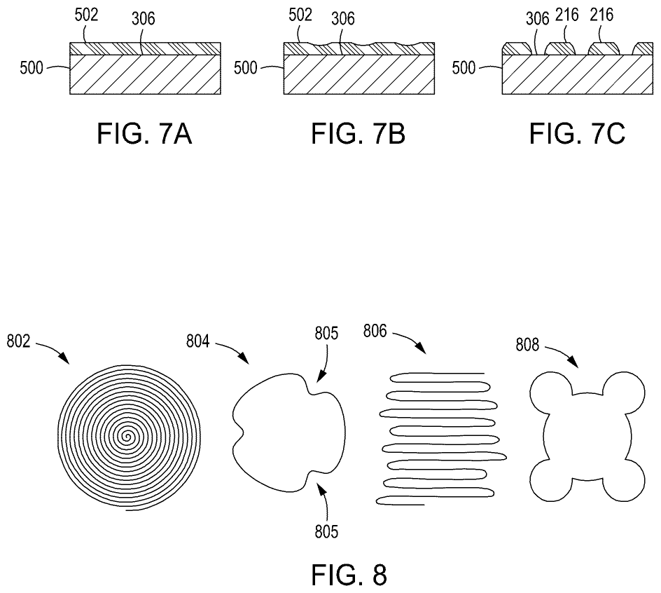

The surface of the part may be an upper surface of the part. In some embodiments, the surface of the part includes a gasket groove (e.g., gasket groove 214), as shown in FIGS. 2, 5A-5C, and FIGS. 6A-6C and applying the elastomer material comprises filling the gasket groove. In some embodiments, the surface is a planar surface with no gasket grooves, as shown in FIGS. 7A-7C and the elastomer material is applied to a substantially flat surface of the part. In some embodiments, applying the elastomer material comprises applying the elastomer material on an entirety of the surface.

The methods of the present disclosure may be used in the formation of gaskets for any type of part used in the manufacturing of substrates. In some embodiments, the part is made of metal. For example, but not meant to be limiting, FIG. 2 depicts a cross-sectional view of a process chamber 200 in accordance with at least some embodiments of the present disclosure. The process chamber 200 has walls 202 that enclose a substrate support 204 and a processing volume 228. The substrate support 204 is used to support a substrate 206 during processing. The process chamber 200 may be used in chemical vapor deposition (CVD) processes and includes a showerhead 220 and a cooling apparatus 212. In some embodiments, the part may be the cooling apparatus 212. A transfer slot 210 may be disposed in a sidewall of the walls 202 to facilitate transferring of the substrate 206 into and out of the processing volume 228. A slit valve 208 may be disposed adjacent the transfer slot 210 to selectively open or close the transfer slot 210.

The showerhead 220 includes gas channels 224 and gas nozzles 222 to distribute gas from a gas supply 226 into the processing volume 228. The cooling apparatus 212 includes an elastomer gasket 216 that is positioned within a gasket groove 214 to keep the gas channels 224 of the showerhead 220 separated. The cooling apparatus 212 is connected to a cooling liquid supply 218. The inventors observed that the process chamber 200 had thermal and gas leak damage on the showerhead 220 after substrate processing. Upon further inspection, poor sealing of the elastomer gasket 216 was causing leakage between the gas channels 224.

FIG. 3 depicts a cross-sectional top view of a cooling apparatus 212 with a gasket groove 214 on a surface 306 of the cooling apparatus 212 that is in a spiral shape in accordance with at least some embodiments of the present disclosure. As depicted in bottom-up view 300 of FIG. 3, the cooling apparatus 212 has a gasket groove 214 that spirals from the center outward. The cross-sectional view of FIG. 2 is approximated by the dashed line 302 of FIG. 3.

Referring back to FIG. 1, in some embodiments, the method 100 includes heating the part prior to applying the elastomer material. In some embodiments, the method 100 includes cleaning the part in a suitable manner prior to applying the elastomer material. In some embodiments, the method 100 includes adjusting or determining a desired dimension of the elastomer gasket to compensate for changes to the sealing surface caused by cleaning the part.

At 104, the method 100 optionally includes curing the elastomer material after applying the elastomer material on the surface. In some embodiments, the curing is conducted via a heat treatment or ultraviolet radiation treatment. For example, the elastomer material may be heated to temperatures greater than 100 degrees Celsius to cure. Curing the elastomer material bonds the elastomer material to the part and provides enhanced adhesion between the part and the elastomer material, especially for embodiments where the part does not include gasket grooves.

At 106, the method 100 includes laser engraving, or laser etching, the elastomer material via a laser (e.g., laser engraving machine 400) to form the elastomer gasket (e.g., elastomer gasket 216) to define a sealing surface on the part. The laser may be any machine suitable for laser engraving, for example having a CO₂ laser, a cold ultraviolet (UV) laser, a green laser, or the like. In some embodiments, the sealing surface is arranged in a spiral pattern such as depicted in FIG. 3. Laser engraving advantageously allows for the formation of elastomer gaskets having complex shapes with enhanced dimensional accuracy. In some embodiments, the laser engraving is performed within an hour of applying the elastomer material.

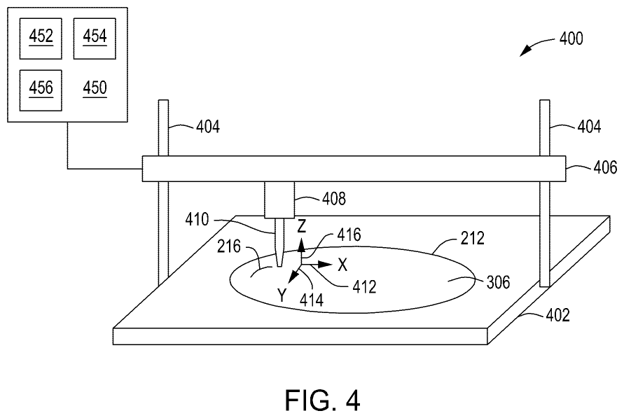

FIG. 4 depicts an isometric view of a laser engraving machine 400 in accordance with at least some embodiments of the present disclosure. The laser engraving machine 400 may be used to form the elastomer gasket 216 on a surface of the cooling apparatus 212 as depicted in FIG. 4. The laser engraving machine 400 has a base 402 that holds the cooling apparatus 412 as a laser head 408 directs photon energy to the elastomer material to remove desired portions of the elastomer material through a nozzle 410. In some embodiments, the laser head 408 moves back and forth in an X direction 412 on a laser head support 406.

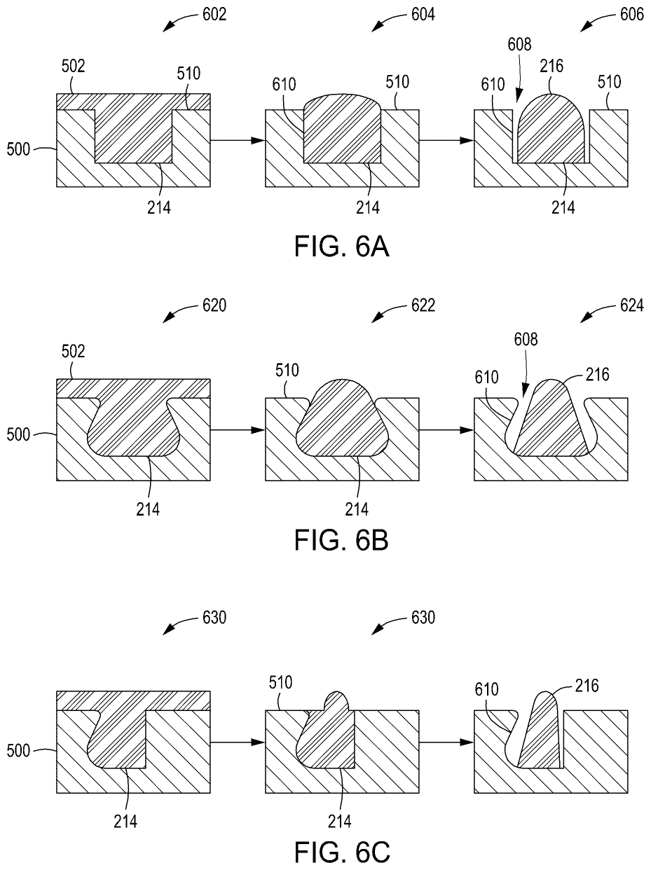

The laser head support 406 is held above the base 402 by supports 404. In some embodiments, the laser head 408 and nozzle 410 may also move back and forth in a Y direction 414 or the base 402 may move back and forth in a Y direction. By controlling the X and Y directions, the laser head 408 and nozzle 410 can create linear and non-linear gasket open loop shapes and/or closed loop shapes (e.g., curves, rectangles, circles, spirals, etc.) in one or more passes. In an example depicted in FIG. 6, a non-linear gasket example shows the laser head 408 and nozzle 410 forming the elastomer gasket 216 in a spiral pattern. The laser head 408 and nozzle 410 may also move in a Z direction 416.

FIG. 8 depicts cross-sectional views of non-limiting gasket profiles in accordance with at least some embodiments of the present disclosure. For example, gasket profile 802 is a spiral shaped profile having an open loop. In some embodiments, engraving the elastomer material via the laser forms the elastomer gasket in 216 a spiral shape. Gasket profile 804 is a closed loop profile having a plurality of indents 805. Gasket profile 806 is an example of a non-linear open loop, or zig zag, profile. Gasket profile 808 is an example of an irregular closed loop profile.

Returning back to FIG. 4, the laser engraving machine 400 may also include a controller 450 that has a computer processing unit (CPU) 452, a memory 454, and supporting circuits 456. The controller 450 allows the contact printer to adjust the desired dimensions of the elastomer gasket based on dimensions of a sealing surface (3D sealing surfaces such as sides and bottom of the gasket groove 214 or planar sealing surfaces discussed below), number of cleaning cycles a part has undergone, and/or based on other properties such as nonuniformity of a part or nonuniformity of the gasket groove. The controller 450 can also be used to change the desired shape of the profile of the elastomer gasket during or prior to laser engraving of the elastomer material, and/or to change or alter the open loop shape or the closed loop shape of the elastomer gasket during or prior to forming of the elastomer gasket.

An example of laser engraving in multiple passes is depicted in FIGS. 5A through 5C. FIG. 5A depicts a schematic side view of a part 500 after applying an elastomer material 502 on a surface 306 of the part 500 having gasket grooves 214 in accordance with at least some embodiments of the present disclosure. In some embodiments, the part 500 is the cooling apparatus 212. The laser head 408 may be moved along the X direction 412 and the Y direction 414 to remove portions of the elastomer material 502. FIG. 5B depicts a schematic side view of the part 500 after partially completing a laser engraving process on the elastomer material 502. The engraving process is repeated via multiple passes until the elastomer gasket 216 is formed in the gasket groove 214.

FIG. 5C depicts a schematic side view of the part 500 after fully completing a laser engraving process on the elastomer material 502 to form the elastomer gasket 216 according to at least some embodiments of the present disclosure. In some embodiments, laser engraving the elastomer material comprises removing the elastomer material 502 from portions of the surface 306 disposed outside of the gasket groove 214 (e.g., surface 510) after fully completing the laser engraving process. In some embodiments, the elastomer gasket 216 extends vertically above the surface 510 so that the elastomer gasket 216 may compress when a second part is coupled to the part 500, creating a seal between the part 500 and the second part.

The elastomer gasket 216 may have any suitable cross-section profile. In some embodiments, the elastomer gasket 216 has a cross-section profile of a circle, a rectangle, a polygon, a triangle, or a body having a rounded top. The gasket groove 214 may have any suitable cross-section profile. For example, FIG. 6A depicts schematic side views of a portion of a part having a first type of a gasket groove 214 at various points of gasket formation in accordance with at least some embodiments of the present disclosure.

View 602 of FIG. 6A depicts the elastomer material 502 applied to the gasket groove 214 and the surface 510 of the part 500. In some embodiments, the first type of the gasket groove 214 may have a rectangular profile. View 604 of FIG. 6A depicts the elastomer material 502 after partially completing a laser engraving process on the elastomer material 502. As shown in view 604, the partial laser engraving leaves the surface 510 exposed, but the elastomer material 502 is still in contact with sidewalls 610 of the gasket groove 214. In some embodiments, laser engraving the elastomer material 502 comprises removing a portion of the elastomer material 502 from within the gasket groove 214 so that a gap 608 is formed between the elastomer gasket 216 and the sidewalls 610 when the elastomer gasket 216 is in an uncompressed state. View 606 of FIG. 6A depicts the elastomer material 502 that is fully engraved to form the elastomer gasket 216 having the gap 608. The gap 608 advantageously prevents the formation of trapped air within the gasket groove 214 when the elastomer gasket 216 is compressed. The elastomer gasket 216 can also advantageously be formed so that the gap 608 is substantially uniform about the gasket groove 214 by engraving more elastomer material in regions where the gasket groove 214 is wider.

FIG. 6B depicts schematic side views of a portion of a part 5500 having a second type of a gasket groove 214 at various points of gasket formation in accordance with at least some embodiments of the present disclosure. View 620 of FIG. 6B depicts the elastomer material 502 applied to the gasket groove 214 and the surface 510 of the part 500. In some embodiments, the second type of the gasket groove 214 may have a dovetail profile. View 622 of FIG. 6B depicts the elastomer material 502 after partially completing a laser engraving process on the elastomer material 502. As shown in view 622, the partial laser engraving leaves the surface 510 exposed, but the elastomer material 502 is still in contact with sidewalls 610 of the gasket groove 214. View 624 of FIG. 6B depicts the elastomer material 502 that is fully engraved to form the elastomer gasket 216 and having the gap 608.

FIG. 6C depicts schematic side views of a portion of a part having a third type of gasket groove at various points of gasket formation in accordance with at least some embodiments of the present disclosure. View 630 of FIG. 6C depicts the elastomer material 502 applied to the gasket groove 214 and the surface 510 of the part 500. In some embodiments, the third type of the gasket groove 214 may have an asymmetrical profile, such as a half dovetail profile. View 632 of FIG. 6C depicts the elastomer material 502 after partially completing a laser engraving process on the elastomer material 502. As shown in view 624, the partial laser engraving leaves the surface 510 exposed, but the elastomer material 502 is still in contact with sidewalls 610 of the gasket groove 214. View 634 of FIG. 6B depicts the elastomer material 502 that is fully engraved to form the elastomer gasket 216 and having the gap 608.

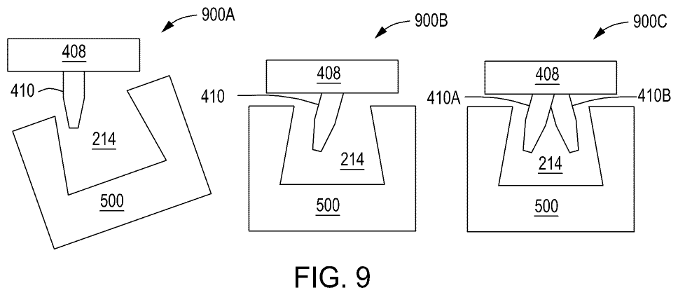

The gasket groove 214 having certain profiles such the dovetail profile of FIG. 6B or the half dovetail profile of FIG. 6C have hard to reach undercut areas. In some embodiments, the method 100 includes tilting at least one of the part or the laser while laser engraving the elastomer material to reach undercut areas of the gasket groove 214. FIG. 9 depicts schematic side views of a laser engraving machine having components that may be tilted to form elastomer gaskets disposed in undercut gasket grooves in accordance with at least some embodiments of the present disclosure. For example, the base 402 of the laser engraving machine 400 can be modified to tilt the part 500 as depicted in view 900A of FIG. 9. In some embodiments, rather than tilt the part 500, the laser head 408 can be modified to include a nozzle 410 that is angled as depicted in view 900B of FIG. 9.

The nozzle 410 that is angled may be fixed at a given angle or may be adjustable to allow engraving while the nozzle 410 is angled to the left or angled to the right. In some embodiments, the angling of the nozzle 410 may be automated to allow the laser head 408 to reach all areas of the sealing surfaces. In some embodiments, the laser head 408 may be modified with two or more nozzles 410A, 410B, as depicted in view 900C of FIG. 9, to allow simultaneously engraving (for faster printing speeds, etc.) or single nozzle engraving without requiring nozzle adjustments for each side of an undercut in a sealing surface.

In some embodiments, the part 500 does not have any gasket grooves. FIG. 7A depicts a schematic side view of a part 500 that does not have any gasket grooves after applying an elastomer material 502 on a surface 306 of the part 500 in accordance with at least some embodiments of the present disclosure. FIG. 7B depicts a schematic side view of the part 500 after partially completing a laser engraving process on the elastomer material 502. FIG. 7C depicts a schematic side view of the part 500 after fully completing the laser engraving process on the elastomer material 502 to form the elastomer gasket 216 in accordance with at least some embodiments of the present disclosure. Forming the elastomer gasket 216 directly on the part 500 advantageously reduces the cost and time associated with forming gasket grooves.

Referring back to FIG. 1, in some embodiments, the method 100 at 108 optionally includes removing the elastomer gasket that is formed, cleaning the part, and applying a new elastomer material on the surface of the part that is cleaned. The new elastomer material is subsequently laser engraved to form a new elastomer gasket in a manner similar to as discussed above. In some embodiments, the new elastomer gasket has a size that is different than the previous elastomer gasket that is removed. In some embodiments, the new elastomer gasket is larger (e.g., wider) than the previous elastomer gasket to advantageously accommodate for an increase in the size of the gasket grooves due to a cleaning cycle. The customization of the size of every new elastomer gasket advantageously increases a working lifetime of the part.

While the foregoing is directed to embodiments of the present disclosure, other and further embodiments of the disclosure may be devised without departing from the basic scope thereof.

1. A method of creating an elastomer gasket, comprising:
applying an elastomer material on a surface of a part used for substrate processing; and
laser engraving the elastomer material to form the elastomer gasket to define a sealing surface on the part.

2. The method of claim 1, further comprising:
cleaning the part prior to forming the elastomer gasket on the sealing surface; and
adjusting a desired dimension of the elastomer gasket to compensate for changes to the sealing surface caused by cleaning the part.

3. The method of claim 2, further comprising:
removing the elastomer gasket that is formed;
cleaning the part;
applying a new elastomer material on the surface of the part; and
laser engraving the new elastomer material to form a new elastomer gasket.

4. The method of claim 1, wherein the surface includes a gasket groove and applying the elastomer material comprises filling the gasket groove.

5. The method of claim 4, wherein laser engraving the elastomer material comprises removing the elastomer material from portions of the surface outside of the gasket groove and removing a portion of the elastomer material from within the gasket groove.

6. The method of claim 4, wherein the gasket groove is spiral shaped, and laser engraving the elastomer material forms the elastomer gasket in a spiral shape.

7. The method of claim 1, wherein the surface is a planar surface with no gasket grooves, and applying the elastomer material comprises applying the elastomer material on an entirety of the surface.

8. The method of claim 1, further comprising:
heating the part prior to applying the elastomer material; and
curing the elastomer material after applying the elastomer material on the surface.

9. The method of claim 1, wherein the part includes gasket grooves, and further comprising tilting at least one of the part or a laser used for laser engraving the elastomer material to reach undercut areas of the gasket groove.

10. A method of creating an elastomer gasket, comprising:
cleaning a part used for substrate processing, the part having a surface that includes a gasket groove for interfacing with an elastomer gasket;
adjusting a desired dimension of the elastomer gasket to compensate for changes to the gasket groove caused by cleaning the part;
applying an elastomer material on the surface; and
laser engraving the elastomer material to form the elastomer gasket with the desired dimension to define a sealing surface.

11. The method of claim 10, further comprising:
forming the elastomer gasket with a cross-section profile of a circle, a rectangle, a polygon, or a triangle.

12. The method of claim 10, wherein the elastomer gasket is formed of one type of material.

13. The method of claim 10, wherein the part is made of metal.

14. The method of claim 10, wherein the sealing surface is arranged in a spiral pattern.

15. The method of claim 10, wherein the elastomer gasket comprises a thermoplastic polyurethane material, a thermoplastic elastomer material, or a thermoplastic copolyester material.

16. The method of claim 10, wherein laser engraving is performed via a CO₂ laser, a cold ultraviolet (UV) laser, or a green laser.

17. The method of claim 10, wherein applying the elastomer material comprises applying a liquid elastomer material via pouring or spin coating.

18. A non-transitory, computer readable medium having instructions stored thereon that, when executed, cause a method for creating an elastomer gasket to be performed, the method comprising:
applying an elastomer material on a surface of a part used for substrate processing; and
laser engraving the elastomer material to form the elastomer gasket to define a sealing surface on the part.

19. The method of the non-transitory, computer readable medium of claim 18, wherein including at least one of:
the surface is a gasket groove and applying the elastomer material comprises filling the gasket groove; or
the surface is a planar surface with no gasket grooves.

20. The method of the non-transitory, computer readable medium of claim 18, further comprising at least one of:
cleaning the part prior to forming the elastomer gasket on the sealing surface;
curing the elastomer material after applying the elastomer material on the surface;
heating the part prior to applying the elastomer material; or
tilting at least one of the part or a laser used for laser engraving the elastomer material.
